(19) United States
(12) Patent Application Publication
(10) Pub. No.: US 2025/0096749 A1
(43) Pub. Date: Mar. 20, 2025

(54) POWER AMPLIFIER CIRCUIT

(71) Applicant: Murata Manufacturing Co., Ltd., Kyoto (JP)

(72) Inventors: Seiko NETSU, Kyoto (JP); Masatoshi HASE, Kyoto (JP)

(21) Appl. No.: 18/969,967

(22) Filed: Dec. 5, 2024

Related U.S. Application Data
(63) Continuation of application No. PCT/JP2023/020793, filed on Jun. 5, 2023.

(30) Foreign Application Priority Data
Jun. 8, 2022 (JP) 2022-093337

(51) Int. Cl. H03F 3/21; H03F 3/19; H03F 3/45

(52) U.S. Cl. CPC H03F 3/211; H03F 3/19; H03F 3/45071; H03F 2200/138; H03F 2200/144; H03F 2200/147; H03F 2200/451

(57) ABSTRACT

A power amplifier circuit includes one or a plurality of amplification stages. A first amplification stage includes a first amplifier and a second amplifier that amplify a differential signal, a first capacitor electrically connected between an output terminal of the first amplifier and an input terminal of the second amplifier, a second capacitor electrically connected between an input terminal of the first amplifier and an output terminal of the second amplifier, a first resonant circuit and a first resistor that are electrically connected in series with each other and are electrically connected between the output terminal and the input terminal of the first amplifier, and a second resonant circuit and a second resistor that are electrically connected in series with each other and are electrically connected between the output terminal and the input terminal of the second amplifier.

### CROSS REFERENCE TO RELATED APPLICATION

This is a continuation of International Application No. PCT/JP2023/020793 filed on Jun. 5, 2023 which claims priority from Japanese Patent Application No. 2022-093337 filed on Jun. 8, 2022. The contents of these applications are incorporated herein by reference in their entireties.

### BACKGROUND ART

### Technical Field

The present disclosure relates to a power amplifier circuit.

In some power amplifier circuits including a common-emitter (source) amplifier circuit, gain is reduced by the Miller effect caused by base (gate)-collector (drain) parasitic capacitance.

Patent Document 1 discloses a technique in which, in a differential amplifier circuit, a reduction in gain is suppressed when the Miller effect is reduced by providing cross-coupling capacitors that are cross-coupled and compensating for a decrease in a gate signal due to gate-drain parasitic capacitance.

Patent Document 1: Japanese Unexamined Patent Application Publication No. 2013-191910

### BRIEF SUMMARY

In some wide-band power amplifier circuits, a frequency deviation occurs to gain. The frequency deviation refers to a difference between values of gain when the gain varies according to the frequency of an input signal. It is desirable that the gain be fixed regardless of the frequency of an input signal. In other words, it is desirable that the frequency deviation be small.

Patent Document 1 does not disclose and suggest a reduction in frequency deviation of gain.

The present disclosure has been made in view of the above and aims to reduce a frequency deviation of gain.

A power amplifier circuit according to an aspect of the present disclosure includes one or a plurality of amplification stages. The power amplifier circuit includes a first amplification stage. The first amplification stage includes a first amplifier and a second amplifier that amplify a differential signal, a first capacitor electrically connected between an output terminal of the first amplifier and an input terminal of the second amplifier, a second capacitor electrically connected between an input terminal of the first amplifier and an output terminal of the second amplifier, a first resonant circuit and a first resistor that are electrically connected in series with each other and are electrically connected between the output terminal and the input terminal of the first amplifier, and a second resonant circuit and a second resistor that are electrically connected in series with each other and are electrically connected between the output terminal and the input terminal of the second amplifier.

The present disclosure enables a reduction in frequency deviation of gain.

### BRIEF DESCRIPTION OF THE DRAWINGS

FIG. 1 is a diagram illustrating a configuration of a power amplifier circuit according to a first embodiment.

FIG. 2 is a graph schematically illustrating characteristics of the power amplifier circuit according to the first embodiment.

FIG. 3 is a graph illustrating circuit simulation results of the power amplifier circuit according to the first embodiment.

FIG. 4 is a diagram illustrating a configuration of a power amplifier circuit according to a modification of the first embodiment.

FIG. 5 is a diagram illustrating a configuration of a power amplifier circuit according to a second embodiment.

FIG. 6 is a diagram illustrating a configuration of an amplifier of the power amplifier circuit according to the second embodiment.

FIG. 7 is a diagram illustrating a configuration of a bias circuit of the power amplifier circuit according to the second embodiment.

FIG. 8 is a graph illustrating circuit simulation results of the power amplifier circuit according to the second embodiment.

FIG. 9 is a diagram illustrating a configuration of a power amplifier circuit according to a third embodiment.

FIG. 10 is a graph illustrating circuit simulation results of the power amplifier circuit according to the third embodiment.

FIG. 11 is a diagram illustrating a configuration of a power amplifier circuit according to a fourth embodiment.

FIG. 12 is a graph illustrating circuit simulation results of the power amplifier circuit according to the fourth embodiment.

FIG. 13 is a diagram illustrating a configuration of a power amplifier circuit according to a fifth embodiment.

FIG. 14 is a graph illustrating circuit simulation results of the power amplifier circuit according to the fifth embodiment.

FIG. 15 is a diagram illustrating a configuration of a power amplifier circuit according to a sixth embodiment.

FIG. 16 is a diagram illustrating a configuration of a power amplifier circuit according to a seventh embodiment.

FIG. 17 is a diagram illustrating a configuration of a power amplifier circuit according to an eighth embodiment.

FIG. 18 is a diagram illustrating a configuration of a power amplifier circuit according to a ninth embodiment.

FIG. 19 is a diagram illustrating a configuration of a power amplifier circuit according to a tenth embodiment.

### DETAILED DESCRIPTION

Embodiments of the present disclosure will be described in detail below with reference to the drawings. Note that the present disclosure is not to be limited by these embodiments. The embodiments are merely illustrative, and it goes without necessarily saying that configurations described in different embodiments can be partially replaced or combined.

### First Embodiment

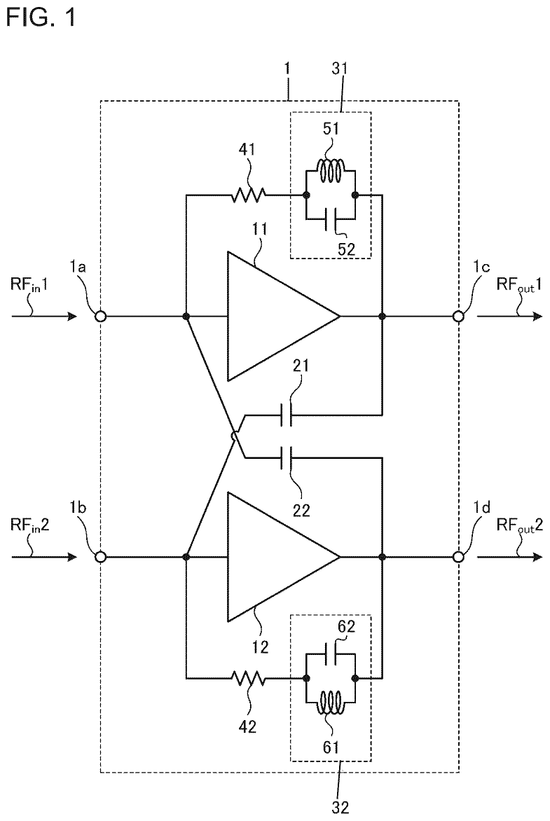

FIG. 1 is a diagram illustrating a configuration of

a power amplifier circuit according to a first embodiment. A power amplifier circuit 1 is a single-stage differential amplifier circuit.

A first input radio-frequency signal RFᵢₙ1 and a second input radio-frequency signal RFᵢₙ2 that constitute a differential signal are respectively input to a first input terminal 1a and a second input terminal 1b of the power amplifier circuit 1. The power amplifier circuit 1 amplifies the first input radio-frequency signal RFᵢₙ1 and the second input radio-frequency signal RFᵢₙ2. The power amplifier circuit 1 respectively outputs a first output radio-frequency signal RFₒᵤₜ1 and a second output radio-frequency signal RFₒᵤₜ2 that constitute a differential signal from a first output terminal 1c and a second output terminal 1d.

The first input radio-frequency signal RFᵢₙ1 is a signal of a first polarity (for example, positive polarity). The second input radio-frequency signal RFᵢₙ2 is a signal of a second polarity (for example, negative polarity). The first output radio-frequency signal RFₒᵤₜ1 is a signal of the second polarity. The second output radio-frequency signal RFₒᵤₜ2 is a signal of the first polarity.

Although an example is given in which a fractional band width of the first input radio-frequency signal RFᵢₙ1 and the second input radio-frequency signal RFᵢₙ2 ranges from about 40 percent (%) to about 60%, the present disclosure is not limited to this. The fractional band width is a value obtained by dividing a band width by a center frequency. For example, when a band ranges from 3.3 gigahertz (GHz) to 5 GHz, a band width is 1.7 GHZ, and a center frequency is 4.15 GHz. Thus, a fractional band width is about 41%.

The power amplifier circuit 1 includes amplifiers 11 and 12, capacitors 21 and 22, resonant circuits 31 and 32, and resistors 41 and 42.

The amplifier 11 corresponds to an example of a first amplifier in the present disclosure. The amplifier 12 corresponds to an example of a second amplifier in the present disclosure. The amplifiers 11 and 12 correspond to an example of a first amplification stage in the present disclosure. The capacitor 21 corresponds to an example of a first capacitor in the present disclosure. The capacitor 22 corresponds to an example of a second capacitor in the present disclosure. The resonant circuit 31 corresponds to an example of a first resonant circuit in the present disclosure. The resonant circuit 32 corresponds to an example of a second resonant circuit in the present disclosure. The resistor 41 corresponds to an example of a first resistor in the present disclosure. The resistor 42 corresponds to an example of a second resistor in the present disclosure.

Each of the amplifiers 11 and 12 is an inverting amplifier. Although an example of the inverting amplifier is a common-emitter (source) amplifier, the present disclosure is not limited to this. The amplifiers 11 and 12 amplify a differential signal and constitute a pair of differential amplifiers.

Although an example is given in which the amplifier 11 and the amplifier 12 are the same in terms of electrical characteristics, the present disclosure is not limited to this.

An input terminal of the amplifier 11 is electrically connected to the first input terminal la. An output terminal of the amplifier 11 is electrically connected to the first output terminal 1c.

An input terminal of the amplifier 12 is electrically connected to the second input terminal 1b. An output terminal of the amplifier 12 is electrically connected to the second output terminal 1d.

One end of the capacitor 21 is electrically connected to the output terminal of the amplifier 11. The other end of the capacitor 21 is electrically connected to the input terminal of the amplifier 12.

One end of the capacitor 22 is electrically connected to the output terminal of the amplifier 12. The other end of the capacitor 22 is electrically connected to the input terminal of the amplifier 11.

That is, the capacitors 21 and 22 are cross-coupling capacitors that are cross-coupled.

Although an example is given in which the capacitor 21 and the capacitor 22 are the same in terms of electrostatic capacity, the present disclosure is not limited to this.

The resonant circuit 31 is an LC parallel resonant circuit including an inductor 51 and a capacitor 52 connected in parallel with each other. Although an example is given in which a resonant frequency of the resonant circuit 31 is set at not less than a maximum frequency of a frequency band of the first input radio-frequency signal RFᵢₙ1 and the second input radio-frequency signal RFᵢₙ2, the present disclosure is not limited to this. For example, when the frequency band of the first input radio-frequency signal RFᵢₙ1 and the second input radio-frequency signal RFᵢₙ2 ranges from 3.3 GHZ to 5 GHZ, an example is given in which the resonant frequency of the resonant circuit 31 is set at 5 GHZ.

One end of the inductor 51 and one end of the capacitor 52 are electrically connected to the output terminal of the amplifier 11. The other end of the inductor 51 and the other end of the capacitor 52 are electrically connected to one end of the resistor 41. The other end of the resistor 41 is electrically connected to the input terminal of the amplifier 11.

That is, feedback is applied to the amplifier 11 by the resonant circuit 31 and the resistor 41. Specifically, they function as a negative feedback circuit.

The resonant circuit 32 is an LC parallel resonant circuit including an inductor 61 and a capacitor 62 connected in parallel with each other. Although an example is given in which a resonant frequency of the resonant circuit 32 is set at not less than a maximum frequency of a frequency band of the first input radio-frequency signal RFᵢₙ1 and the second input radio-frequency signal RFᵢₙ2, the present disclosure is not limited to this. For example, when the frequency band of the first input radio-frequency signal RFᵢₙ1 and the second input radio-frequency signal RFᵢₙ2 ranges from 3.3 GHZ to 5 GHZ, an example is given in which the resonant frequency of the resonant circuit 32 is set at 5 GHz.

Although an example is given in which the resonant circuit 31 and the resonant circuit 32 are the same in terms of resonant frequency, the present disclosure is not limited to this.

One end of the inductor 61 and one end of the capacitor 62 are electrically connected to the output terminal of the amplifier 12. The other end of the inductor 61 and the other end of the capacitor 62 are electrically connected to one end of the resistor 42. The other end of the resistor 42 is electrically connected to the input terminal of the amplifier 12.

That is, feedback is applied to the amplifier 12 by the resonant circuit 32 and the resistor 42. Specifically, they function as a negative feedback circuit.

Although an example is given in which the resistor 41 and the resistor 42 are the same in terms of resistance value, the present disclosure is not limited to this.

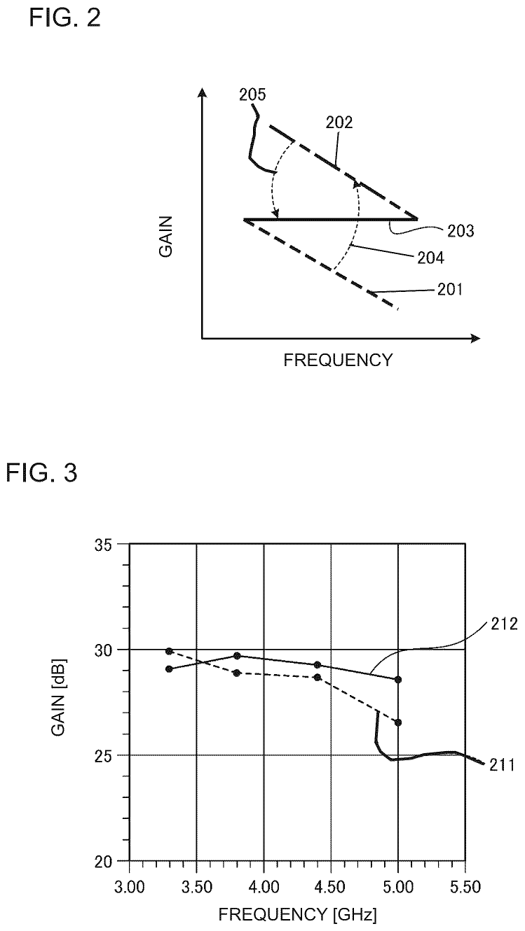

FIG. 2 is a graph schematically illustrating characteristics of the power amplifier circuit according to the first embodiment. In FIG. 2, the horizontal axis represents frequency, and the vertical axis represents gain.

A chain line 201 represents characteristics of the power amplifier circuit 1 exhibited when the capacitors 21 and 22, the resonant circuits 31 and 32, and the resistors 41 and 42 are not provided. In this case, as indicated by the chain line 201, the gain of the power amplifier circuit 1 decreases as the frequency increases.

A dashed-dotted line 202 represents characteristics of the power amplifier circuit 1 exhibited when the capacitors 21 and 22 are provided and the resonant circuits 31 and 32 and the resistors 41 and 42 are not provided. The capacitors 21 and 22 can reduce the Miller effect. Consequently, as indicated by an arrow 204, the gain of the power amplifier circuit 1 increases as a whole from the chain line 201 to the dashed-dotted line 202.

A solid line 203 represents characteristics of the power amplifier circuit 1 exhibited when the capacitors 21 and 22, the resonant circuits 31 and 32, and the resistors 41 and 42 are provided.

The resonant frequencies of the respective resonant circuits 31 and 32 are set at not less than a maximum frequency of the frequency band of the first input radio-frequency signal RFᵢₙ1 and the second input radio-frequency signal RFᵢₙ2. Hence, as for each of the resonant circuits 31 and 32, the LC resonant circuit turns into an open circuit in a high frequency range to thus interrupt the feedback circuit, and the LC resonant circuit turns into a capacitive circuit in a low frequency range to thus bring the feedback circuit into conduction. Consequently, as indicated by an arrow 205, the gain of the power amplifier circuit 1 remains almost unchanged in the high frequency range and decreases in the low frequency range. Thus, a frequency deviation of the gain of the power amplifier circuit 1 is kept from occurring as indicated by the solid line 203.

FIG. 3 is a graph illustrating circuit simulation results of the power amplifier circuit according to the first embodiment. In FIG. 3, the horizontal axis represents frequency (GHz), and the vertical axis represents gain (decibel (dB)) at an output of 33 dBm.

A chain line 211 represents characteristics of the power amplifier circuit 1 exhibited when the capacitors 21 and 22, the resonant circuits 31 and 32, and the resistors 41 and 42 are not provided.

A solid line 212 represents characteristics of the power amplifier circuit 1 exhibited when the capacitors 21 and 22, the resonant circuits 31 and 32, and the resistors 41 and 42 are provided.

In the power amplifier circuit 1, as indicated by the solid line 212, the gain is reduced in a low frequency range, and the gain is increased in a high frequency range, thereby enabling a reduction in frequency deviation of gain.

### (Modification)

In the first embodiment, although each of the resonant circuits 31 and 32 is an LC parallel resonant circuit, the present disclosure is not limited to this. The resonant circuit may be an LC series resonant circuit.

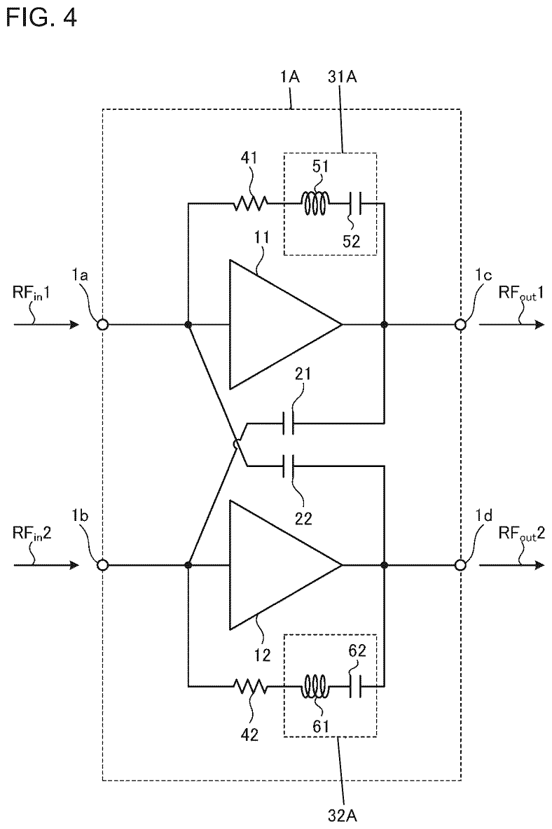

FIG. 4 is a diagram illustrating a configuration of a power amplifier circuit according to a modification of the first embodiment. A power amplifier circuit 1A is a single-stage differential amplifier circuit.

In comparison with the power amplifier circuit 1 (see FIG. 1), the power amplifier circuit 1A includes resonant circuits 31A and 32A in place of the resonant circuits 31 and 32.

The resonant circuit 31A corresponds to an example of the first resonant circuit in the present disclosure. The resonant circuit 32A corresponds to an example of the second resonant circuit in the present disclosure.

The resonant circuit 31A is an LC series resonant circuit including the inductor 51 and the capacitor 52 connected in series with each other. Although an example is given in which a resonant frequency of the resonant circuit 31A is set at not more than a minimum frequency of a frequency band of the first input radio-frequency signal RFᵢₙ1 and the second input radio-frequency signal RFᵢₙ2, the present disclosure is not limited to this. For example, when the frequency band of the first input radio-frequency signal RFᵢₙ1 and the second input radio-frequency signal RFᵢₙ2 ranges from 3.3 GHZ to 5 GHZ, an example is given in which the resonant frequency of the resonant circuit 31A is set at 3.3 GHZ.

The resonant circuit 32A is an LC series resonant circuit including the inductor 61 and the capacitor 62 connected in series with each other. Although an example is given in which a resonant frequency of the resonant circuit 32A is set at not more than a minimum frequency of a frequency band of the first input radio-frequency signal RFᵢₙ1 and the second input radio-frequency signal RFᵢₙ2, the present disclosure is not limited to this. For example, when the frequency band of the first input radio-frequency signal RFᵢₙ1 and the second input radio-frequency signal RFᵢₙ2 ranges from 3.3 GHZ to 5 GHZ, an example is given in which the resonant frequency of the resonant circuit 32A is set at 3.3 GHZ.

Although an example is given in which the resonant circuit 31A and the resonant circuit 32A are the same in terms of resonant frequency, the present disclosure is not limited to this.

Since the resonant frequencies of the respective resonant circuits 31A and 32A are set at not more than a minimum frequency of the frequency band of the first input radio-frequency signal RFᵢₙ1 and the second input radio-frequency signal RFᵢₙ2, the LC resonant circuit turns into a capacitive circuit in a low frequency range to thus bring a feedback path into conduction, and the LC resonant circuit turns into an open circuit in a high frequency range to thus interrupt the feedback path. Consequently, in the power amplifier circuit 1A, gain is reduced in the low frequency range, and the gain is increased in the high frequency range, thereby enabling a reduction in frequency deviation of gain.

### Second Embodiment

Of components in a second embodiment, components that are the same as components in the first embodiment are denoted by the same reference signs, and a description thereof is omitted.

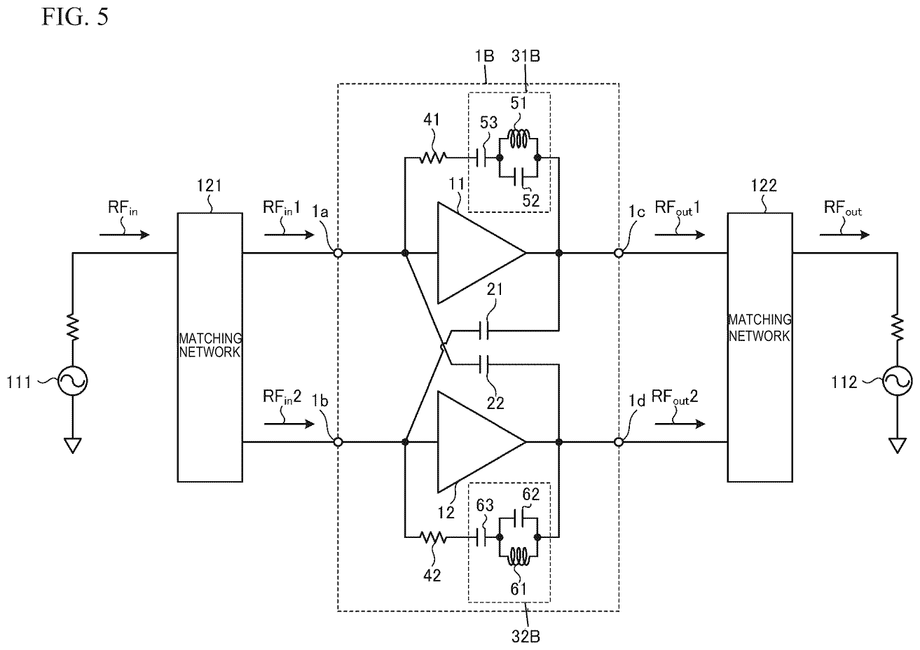

FIG. 5 is a diagram illustrating a configuration of a power amplifier circuit according to the second embodiment. A power amplifier circuit 1B is a single-stage differential amplifier circuit.

In comparison with the power amplifier circuit 1 (see FIG. 1), the power amplifier circuit 1B includes resonant circuits 31B and 32B in place of the resonant circuits 31 and 32.

The resonant circuit 31B corresponds to an example of the first resonant circuit in the present disclosure. The resonant circuit 32B corresponds to an example of the second resonant circuit in the present disclosure.

In comparison with the resonant circuit 31 (see FIG. 1), the resonant circuit 31B further includes a capacitor 53. One end of the capacitor 53 is electrically connected to the other ends of the inductor 51 and the capacitor 52. The other end of the capacitor 53 is electrically connected to the one end of the resistor 41.

The capacitor 53 serves as a DC cut capacitor.

In comparison with the resonant circuit 32 (see FIG. 1), the resonant circuit 32B further includes a capacitor 63. One end of the capacitor 63 is electrically connected to the other ends of the inductor 61 and the capacitor 62. The other end of the capacitor 63 is electrically connected to the one end of the resistor 42.

The capacitor 63 serves as a DC cut capacitor.

Effects of the capacitors 53 and 63 will be described.

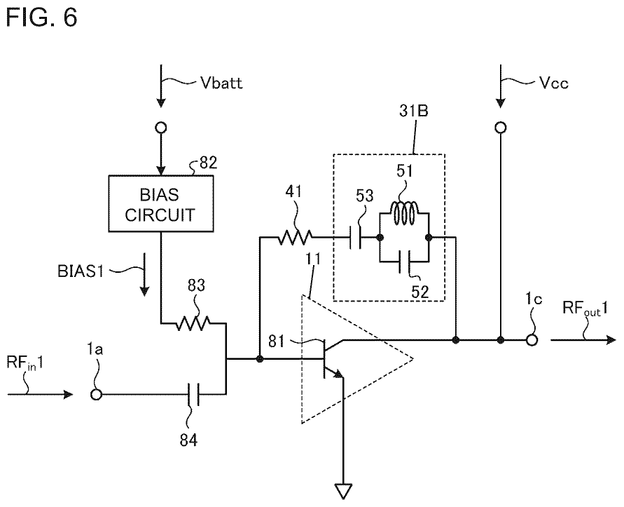

FIG. 6 is a diagram illustrating a configuration of an amplifier of the power amplifier circuit according to the second embodiment. FIG. 6 illustrates the amplifier 11 and its peripheral circuitry. A configuration of the amplifier 12 and its peripheral circuitry is similar to that of the amplifier 11 and its peripheral circuitry, and thus an illustration and description thereof is omitted. The amplifier 11 includes a transistor 81.

In embodiments, although a transistor is a bipolar transistor, the present disclosure is not limited to this. The transistor may be a Field Effect Transistor (FET). If the transistor is an FET, a source corresponds to an emitter, a gate corresponds to a base, and a drain corresponds to a collector.

An emitter of the transistor 81 is electrically connected to a reference potential. Although an example is given in which the reference potential is a ground potential, the present disclosure is not limited to this.

A power supply voltage Vcc is input to a collector of the transistor 81.

A power supply voltage Vbatt is input to a bias circuit 82. The bias circuit 82 outputs a bias current BIAS1 to a base of the transistor 81 via a resistor 83.

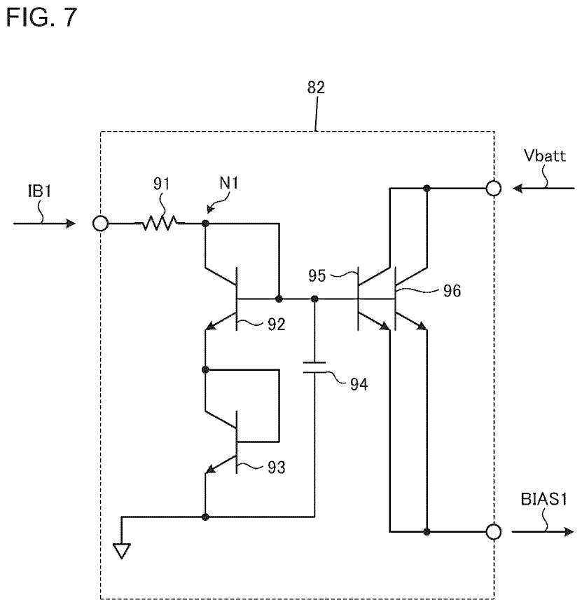

FIG. 7 is a diagram illustrating a configuration of the bias circuit of the power amplifier circuit according to the second embodiment.

The bias circuit 82 includes a resistor 91, transistors 92, 93, 95, and 96, and a capacitor 94.

A control current IB1 is input to one end of the resistor 91. The other end of the resistor 91 is electrically connected to a node N1.

A collector and a base of the transistor 92 are electrically connected to the node N1. That is, the transistor 92 is diode-connected. An emitter of the transistor 92 is electrically connected to a collector and a base of the transistor 93. That is, the transistor 93 is diode-connected. An emitter of the transistor 93 is electrically connected to the reference potential.

The transistors 92 and 93 generate a fixed voltage. The voltage generated by the transistors 92 and 93 is a voltage at the node N1.

One end of the capacitor 94 is electrically connected to the node N1. The other end of the capacitor 94 is electrically connected to the reference potential. The capacitor 94 stabilizes the voltage at the node N1.

The power supply voltage Vbatt is input to collectors of the transistors 95 and 96. Bases of the transistors 95 and 96 are electrically connected to the node N1. Emitters of the transistors 95 and 96 are electrically connected to one end of the resistor 83 (see FIG. 6). That is, the transistors 95 and 96 are connected so as to establish an emitter-follower connection. The transistors 95 and 96 output the bias current BIAS1 from the emitters to the one end of the resistor 83.

Referring back to FIG. 6, the first input radio-frequency signal RFᵢₙ1 is input to the base of the transistor 81 via a capacitor 84.

In recent years, the power supply voltage Vcc is changed during amplification operation in some cases. Although, as an example, an envelope tracking method is given in which the power supply voltage Vcc is changed (adjusted) in accordance with an envelope of the first input radio-frequency signal RFᵢₙ1, the present disclosure is not limited to this.

If the capacitor 53 is not provided, when the power supply voltage Vcc changes, a change in the power supply voltage Vcc is conducted to the base of the transistor 81 via the inductor 51 and the resistor 41, and a base bias point of the transistor 81 changes.

On the other hand, if the capacitor 53 is provided, even when the power supply voltage Vcc changes, a change in the power supply voltage Vcc is interrupted by the capacitor 53, and thus a change in the base bias point of the transistor 81 is reduced.

Thus, when the resonant circuit 31B includes the capacitor 53, even when the power supply voltage Vcc changes, the base bias point of the transistor 81 can be kept from changing.

Hence, the bias circuit 82 can determine the base bias point of the transistor 81 and control operating classes (class A, class B, class C, and so forth) of the amplifier 11.

Incidentally, as for the resonant circuit 31A (see FIG. 4), which is an LC series resonant circuit, the capacitor 52 serves as a DC cut capacitor, and thus no DC cut capacitor has to be added.

Referring back to FIG. 5, a matching network 121 is electrically connected to the first input terminal 1a and the second input terminal 1b. A signal source 111 is electrically connected to the matching network 121. The matching network 121 provides impedance matching between the signal source 111 and the power amplifier circuit 1B.

The signal source 111 outputs a single-ended input radio-frequency signal RFᵢₙ to the matching network 121. The matching network 121 converts the single-ended input radio-frequency signal RFᵢₙ into a first input radio-frequency signal RFᵢₙ1 and a second input radio-frequency signal RFᵢₙ2 that constitute a differential signal and respectively outputs the first input radio-frequency signal RFᵢₙ1 and the second input radio-frequency signal RFᵢₙ2 to the first input terminal 1a and second input terminal 1b.

A matching network 122 is electrically connected to the first output terminal 1c and the second output terminal 1d. A load 112 is electrically connected to the matching network 122. The matching network 122 provides impedance matching between the power amplifier circuit 1B and the load 112.

The power amplifier circuit 1 outputs a first output radio-frequency signal RFₒᵤₜ1 and a second output radio-frequency signal RFₒᵤₜ2 that constitute a differential signal to the matching network 122. The matching network 122 converts the first output radio-frequency signal RFₒᵤₜ1 and the second output radio-frequency signal RFₒᵤₜ2 that constitute a differential signal into a single-ended input radio-frequency signal RFout and outputs the input radio-frequency signal RFout to the load 112.

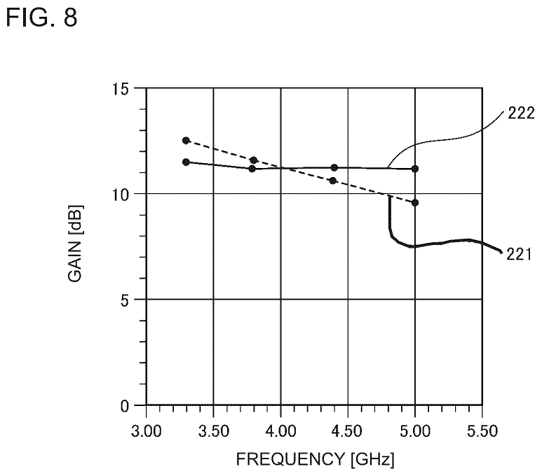

FIG. 8 is a graph illustrating circuit simulation results of the power amplifier circuit according to the second embodiment. In FIG. 8, the horizontal axis represents frequency (GHz), and the vertical axis represents gain (dB) at an output of 33 dBm.

A chain line 221 represents characteristics of the power amplifier circuit 1B exhibited when the capacitors 21 and 22, the resonant circuits 31B and 32B, and the resistors 41 and 42 are not provided.

A solid line 222 represents characteristics of the power amplifier circuit 1B exhibited when the capacitors 21 and 22, the resonant circuits 31B and 32B, and the resistors 41 and 42 are provided.

In the power amplifier circuit 1B, as indicated by the solid line 222, the gain is reduced in a low frequency range, and the gain is increased in a high frequency range, thereby enabling a reduction in frequency deviation of gain.

### Third Embodiment

Of components in a third embodiment, components that are the same as components in the other embodiments are denoted by the same reference signs, and a description thereof is omitted.

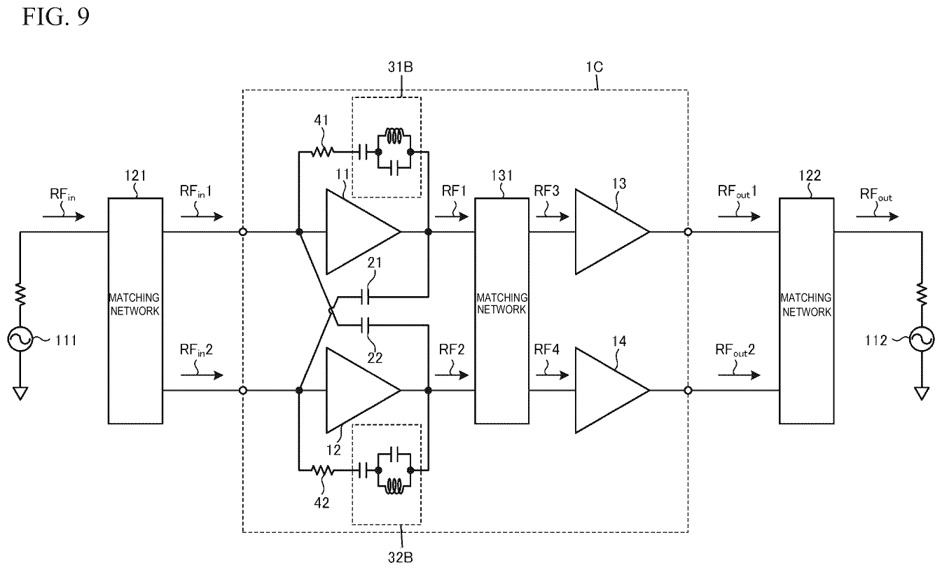

FIG. 9 is a diagram illustrating a configuration of a power amplifier circuit according to the third embodiment. A power amplifier circuit 1C is a two-stage differential amplifier circuit.

In comparison with the power amplifier circuit 1B (see FIG. 5), the power amplifier circuit 1C further includes amplifiers 13 and 14, and a matching network 131.

The amplifier 13 corresponds to an example of a third amplifier in the present disclosure. The amplifier 14 corresponds to an example of a fourth amplifier in the present disclosure. The amplifiers 13 and 14 correspond to an example of a second amplification stage in the present disclosure.

Each of the amplifiers 13 and 14 is an inverting amplifier. The amplifiers 13 and 14 amplify a differential signal and constitute a pair of differential amplifiers.

Although an example is given in which the amplifier 13 and the amplifier 14 are the same in terms of electrical characteristics, the present disclosure is not limited to this.

The matching network 131 is electrically connected between the output terminals of the respective amplifiers 11 and 12 and input terminals of the respective amplifiers 13 and 14. The matching network 131 provides impedance matching between the output terminal of the amplifier 11 and the input terminal of the amplifier 13 and also provides impedance matching between the output terminal of the amplifier 12 and the input terminal of the amplifier 14.

The amplifier 11 outputs a radio-frequency signal RF1 obtained by amplifying the first input radio-frequency signal RFᵢₙ1 to the matching network 131. The amplifier 12 outputs a radio-frequency signal RF2 obtained by amplifying the second input radio-frequency signal RFᵢₙ2 to the matching network 131. The matching network 131 outputs radio-frequency signals RF3 and RF4 constituting a differential signal to the respective amplifiers 13 and 14 in accordance with the radio-frequency signals RF1 and RF2.

The amplifier 13 outputs a first output radio-frequency signal RFₒᵤₜ1 obtained by amplifying the radio-frequency signal RF3 to the matching network 122. The amplifier 14 outputs a second output radio-frequency signal RFₒᵤₜ2 obtained by amplifying the radio-frequency signal RF4 to the matching network 122.

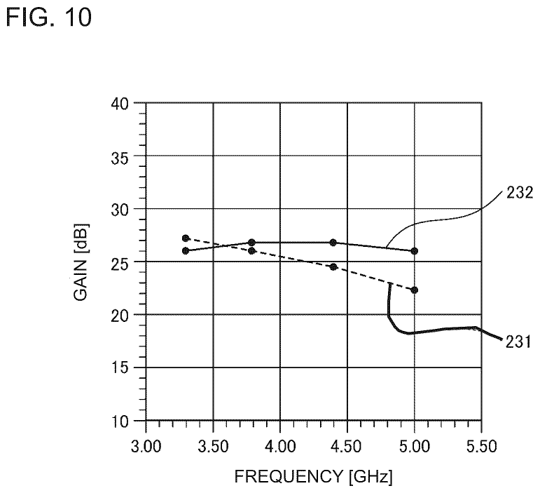

FIG. 10 is a graph illustrating circuit simulation results of the power amplifier circuit according to the third embodiment. In FIG. 10, the horizontal axis represents frequency (GHz), and the vertical axis represents gain (dB) at an output of 33 dBm.

A chain line 231 represents characteristics of the power amplifier circuit 1C exhibited when the capacitors 21 and 22, the resonant circuits 31B and 32B, and the resistors 41 and 42 are not provided.

A solid line 232 represents characteristics of the power amplifier circuit 1C exhibited when the capacitors 21 and 22, the resonant circuits 31B and 32B, and the resistors 41 and 42 are provided.

In the power amplifier circuit 1C, as indicated by the solid line 232, the gain is reduced in a low frequency range, and the gain is increased in a high frequency range, thereby enabling a reduction in frequency deviation of gain.

### Fourth Embodiment

Of components in a fourth embodiment, components that are the same as components in the other embodiments are denoted by the same reference signs, and a description thereof is omitted.

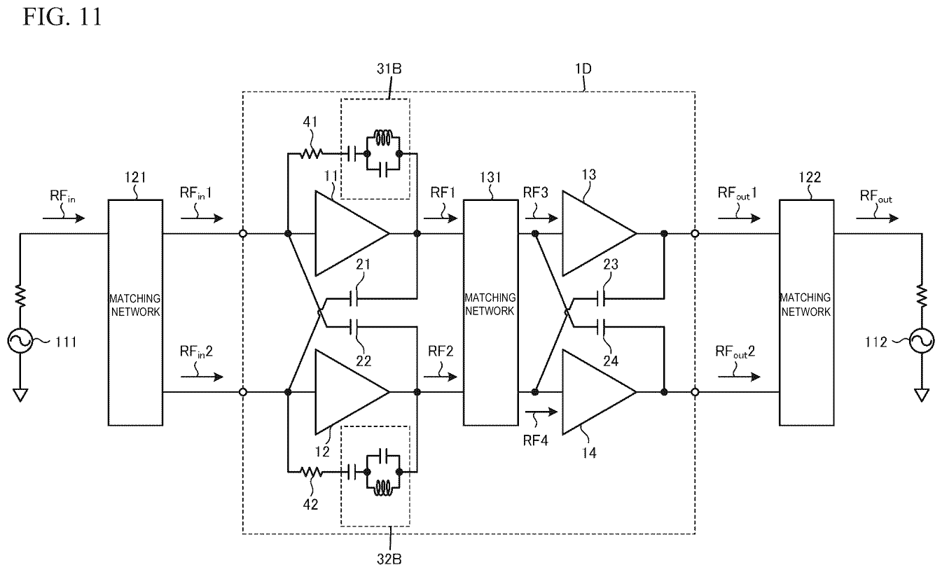

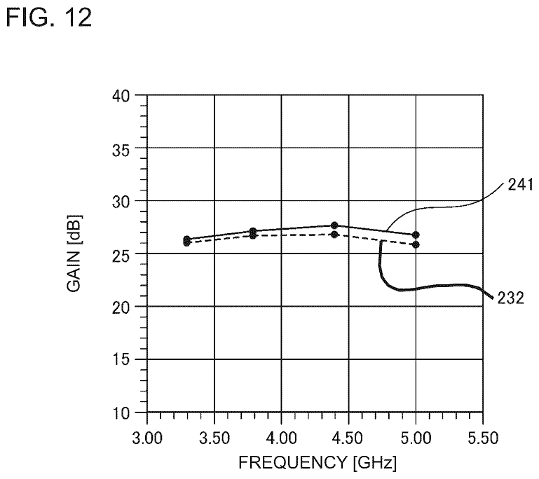

FIG. 11 is a diagram illustrating a configuration of a power amplifier circuit according to the fourth embodiment. A power amplifier circuit 1D is a two-stage differential amplifier circuit.

In comparison with the power amplifier circuit 1C (see FIG. 9), the power amplifier circuit 1D further includes capacitors 23 and 24.

The capacitor 23 corresponds to an example of a third capacitor in the present disclosure. The capacitor 24 corresponds to an example of a fourth capacitor in the present disclosure.

Although an example is given in which the capacitor 23 and the capacitor 24 are the same in terms of electrostatic capacity, the present disclosure is not limited to this.

One end of the capacitor 23 is electrically connected to an output terminal of the amplifier 13. The other end of the capacitor 23 is electrically connected to the input terminal of the amplifier 14.

One end of the capacitor 24 is electrically connected to an output terminal of the amplifier 14. The other end of the capacitor 24 is electrically connected to the input terminal of the amplifier 13.

That is, the capacitors 23 and 24 are cross-coupling capacitors that are cross-coupled.

FIG. 12 is a graph illustrating circuit simulation results of the power amplifier circuit according to the fourth embodiment. In FIG. 12, the horizontal axis represents frequency (GHz), and the vertical axis represents gain (dB) at an output of 33 dBm.

A chain line 232 represents characteristics of the power amplifier circuit 1C (see FIG. 9).

A solid line 241 represents characteristics of the power amplifier circuit 1D.

In comparison with the power amplifier circuit 1C, in the power amplifier circuit 1D, as indicated by the solid line 241, the gain is increased in a high frequency range, thereby enabling a further reduction in frequency deviation of gain.

### Fifth Embodiment

Of components in a fifth embodiment, components that are the same as components in the other embodiments are denoted by the same reference signs, and a description thereof is omitted.

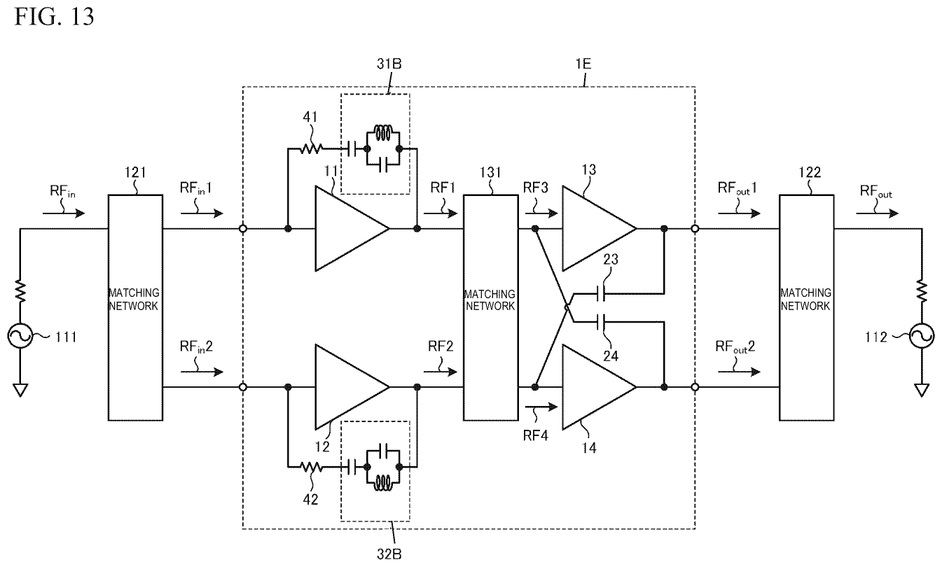

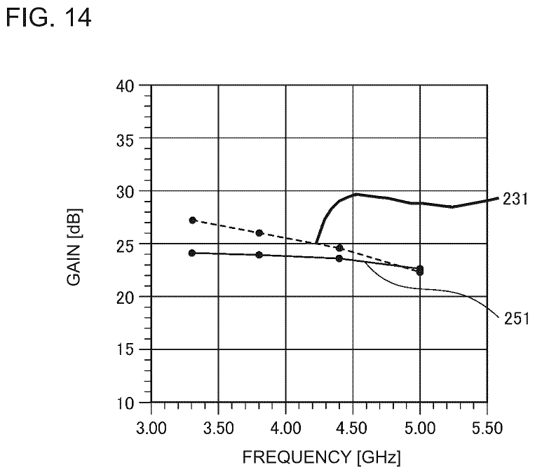

FIG. 13 is a diagram illustrating a configuration of a power amplifier circuit according to the fifth embodiment. A power amplifier circuit 1E is a two-stage differential amplifier circuit.

In comparison with the power amplifier circuit 1D (see FIG. 11), the power amplifier circuit 1E does not include the capacitors 21 and 22.

FIG. 14 is a graph illustrating circuit simulation results of the power amplifier circuit according to the fifth embodiment. In FIG. 14, the horizontal axis represents frequency (GHz), and the vertical axis represents gain (dB) at an output of 33 dBm.

A chain line 231 represents characteristics of the power amplifier circuit 1E exhibited when the capacitors 23 and 24, the resonant circuits 31B and 32B, and the resistors 41 and 42 are not provided.

A solid line 251 represents characteristics of the power amplifier circuit 1E exhibited when the capacitors 23 and 24, the resonant circuits 31B and 32B, and the resistors 41 and 42 are provided.

In the power amplifier circuit 1E, as indicated by the solid line 251, the gain is reduced in a low frequency range, thereby enabling a reduction in frequency deviation of gain.

### Sixth Embodiment

Of components in a sixth embodiment, components that are the same as components in the other embodiments are denoted by the same reference signs, and a description thereof is omitted.

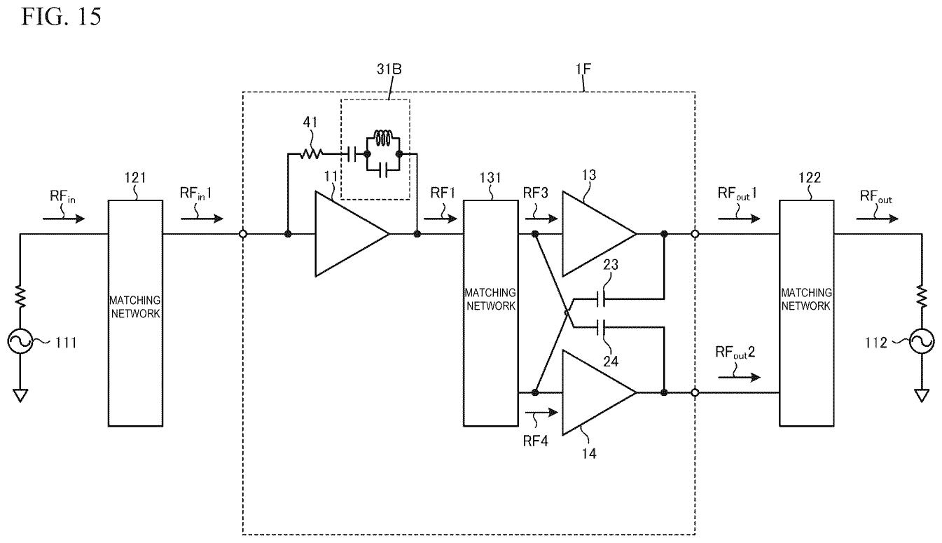

FIG. 15 is a diagram illustrating a configuration of a power amplifier circuit according to the sixth embodiment. A power amplifier circuit 1F is a two-stage differential amplifier circuit.

In comparison with the power amplifier circuit 1E (see FIG. 13), the power amplifier circuit 1F does not include the amplifier 12, the resonant circuit 32B, and the resistor 42. The power amplifier circuit 1F does not include the matching network 121 and the matching network 131 in the power amplifier circuit 1E (see FIG. 13).

That is, a first stage of the power amplifier circuit 1F is a single-ended signal amplification stage, and a second stage is a differential signal amplification stage.

The matching network 121 provides impedance matching between the signal source 111 and the power amplifier circuit 1F. The matching network 131 provides impedance matching and also converts a single-ended radio-frequency signal RF1 into radio-frequency signals RF3 and RF4 constituting a differential signal to output the radio-frequency signals RF3 and RF4 to the respective amplifiers 13 and 14.

As in the power amplifier circuit 1C (see FIG. 9), the power amplifier circuit 1F enables a reduction in frequency deviation of gain.

### Seventh Embodiment

Of components in a seventh embodiment, components that are the same as components in the other embodiments are denoted by the same reference signs, and a description thereof is omitted.

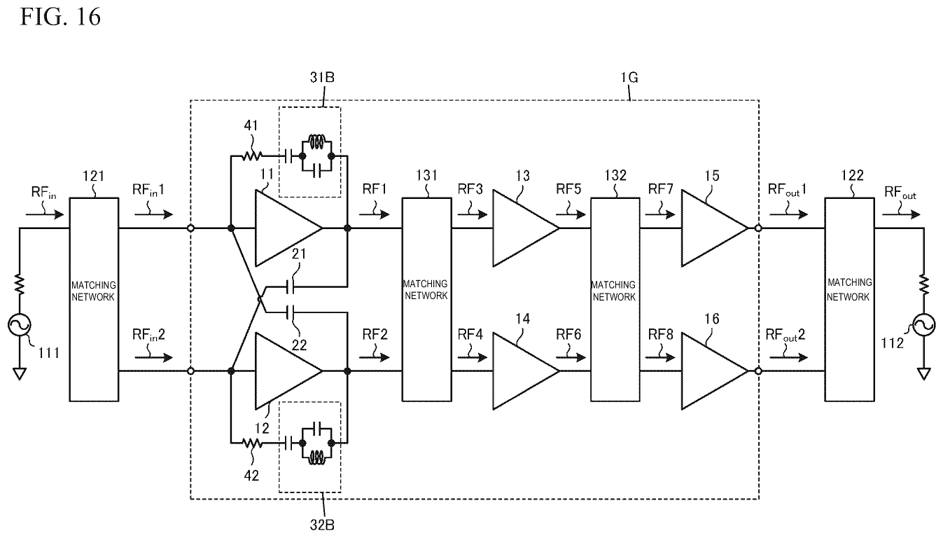

FIG. 16 is a diagram illustrating a configuration of a power amplifier circuit according to the seventh embodiment. A power amplifier circuit 1G is a three-stage differential amplifier circuit.

In comparison with the power amplifier circuit 1C (see FIG. 9), the power amplifier circuit 1G further includes amplifiers 15 and 16, and a matching network 132.

The amplifier 15 corresponds to an example of a fifth amplifier in the present disclosure. The amplifier 16 corresponds to an example of a sixth amplifier in the present disclosure. The amplifiers 15 and 16 correspond to an example of a third amplification stage in the present disclosure.

Each of the amplifiers 15 and 16 is an inverting amplifier. The amplifiers 15 and 16 amplify a differential signal and constitute a pair of differential amplifiers.

Although an example is given in which the amplifier 15 and the amplifier 16 are the same in terms of electrical characteristics, the present disclosure is not limited to this.

The matching network 132 is electrically connected between the output terminals of the respective amplifiers 13 and 14 and input terminals of the respective amplifiers 15 and 16. The matching network 132 provides impedance matching between the output terminal of the amplifier 13 and the input terminal of the amplifier 15 and also provides impedance matching between the output terminal of the amplifier 14 and the input terminal of the amplifier 16.

The amplifier 13 outputs a radio-frequency signal RF5 obtained by amplifying the radio-frequency signal RF3 to the matching network 132. The amplifier 14 outputs a radio-frequency signal RF6 obtained by amplifying the radio-frequency signal RF4 to the matching network 132. The matching network 132 outputs radio-frequency signals RF7 and RF8 constituting a differential signal to the respective amplifiers 15 and 16 in accordance with the radio-frequency signals RF5 and RF6.

The amplifier 15 outputs a first output radio-frequency signal RFₒᵤₜ1 obtained by amplifying the radio-frequency signal RF7 to the matching network 122. The amplifier 16 outputs a second output radio-frequency signal RFₒᵤₜ2 obtained by amplifying the radio-frequency signal RF8 to the matching network 122.

The power amplifier circuit 1G enables a reduction in frequency deviation of gain.

### Eighth Embodiment

Of components in an eighth embodiment, components that are the same as components in the other embodiments are denoted by the same reference signs, and a description thereof is omitted.

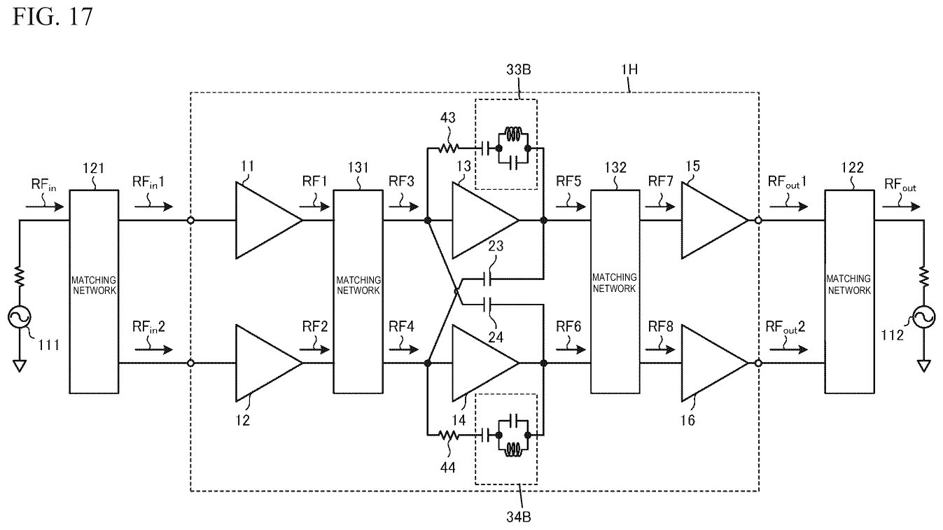

FIG. 17 is a diagram illustrating a configuration of a power amplifier circuit according to the eighth embodiment. A power amplifier circuit 1H is a three-stage differential amplifier circuit.

In comparison with the power amplifier circuit 1G (see FIG. 16), the power amplifier circuit 1H does not include the capacitors 21 and 22, the resonant circuits 31B and 32B, and the resistors 41 and 42. Furthermore, in comparison with the power amplifier circuit 1G, the power amplifier circuit 1H further includes the capacitors 23 and 24, resonant circuits 33B and 34B, and resistors 43 and 44.

The resonant circuit 33B corresponds to an example of a third resonant circuit in the present disclosure. The resonant circuit 34B corresponds to an example of a fourth resonant circuit in the present disclosure. The resistor 43 corresponds to an example of a third resistor in the present disclosure. The resistor 44 corresponds to an example of a fourth resistor in the present disclosure.

The resonant circuits 33B and 34B are respectively similar to the resonant circuits 31B and 32B in terms of circuit configuration and function, and thus a description thereof is omitted.

The power amplifier circuit 1H enables a reduction in frequency deviation of gain.

### Ninth Embodiment

Of components in a ninth embodiment, components that are the same as components in the other embodiments are denoted by the same reference signs, and a description thereof is omitted.

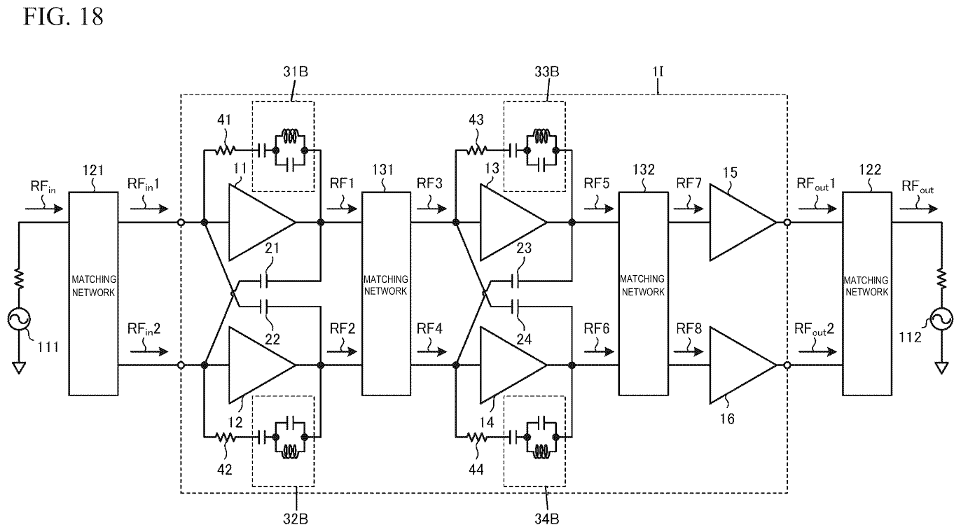

FIG. 18 is a diagram illustrating a configuration of a power amplifier circuit according to the ninth embodiment. A power amplifier circuit 1I is a three-stage differential amplifier circuit.

In comparison with the power amplifier circuit 1G (see FIG. 16), the power amplifier circuit 1I further includes the capacitors 23 and 24, the resonant circuits 33B and 34B, and the resistors 43 and 44.

The power amplifier circuit 1I enables a reduction in frequency deviation of gain.

### Tenth Embodiment

Of components in a tenth embodiment, components that are the same as components in the other embodiments are denoted by the same reference signs, and a description thereof is omitted.

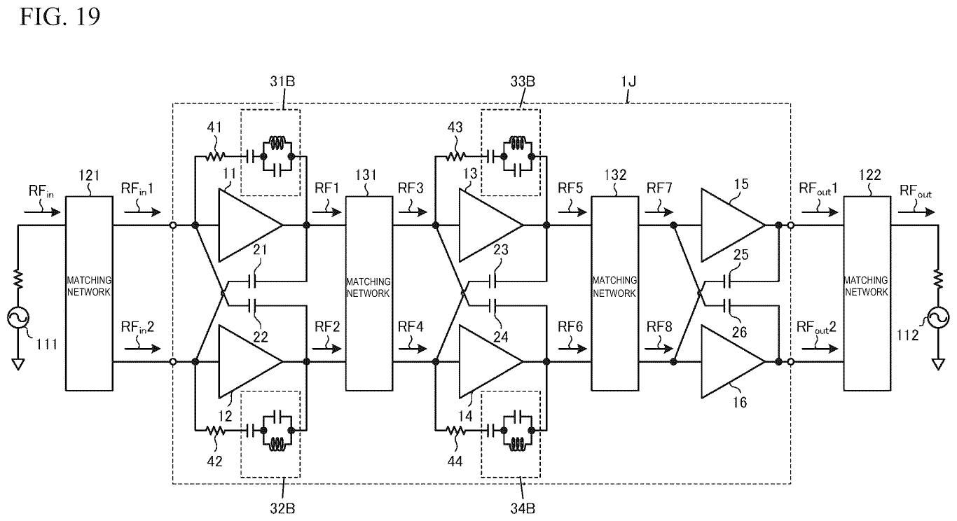

FIG. 19 is a diagram illustrating a configuration of a power amplifier circuit according to the tenth embodiment. A power amplifier circuit 1J is a three-stage differential amplifier circuit.

In comparison with the power amplifier circuit 1I (see FIG. 18), the power amplifier circuit 1J further includes capacitors 25 and 26.

The capacitor 25 corresponds to an example of a fifth capacitor in the present disclosure. The capacitor 26 corresponds to an example of a sixth capacitor in the present disclosure.

Although an example is given in which the capacitor 25 and the capacitor 26 are the same in terms of electrostatic capacity, the present disclosure is not limited to this.

One end of the capacitor 25 is electrically connected to an output terminal of the amplifier 15. The other end of the capacitor 25 is electrically connected to the input terminal of the amplifier 16. One end of the capacitor 26 is electrically

connected to an output terminal of the amplifier 16. The other end of the capacitor 26 is electrically connected to the input terminal of the amplifier 15.

That is, the capacitors 25 and 26 are cross-coupling capacitors that are cross-coupled.

The power amplifier circuit 1J enables a reduction in frequency deviation of gain.

### Appendix

Although single-stage to three-stage power amplifier circuits have been described in the embodiments, the present disclosure is not limited to these. The present disclosure can also be applied to a power amplifier circuit including four or more stages.

### Configuration Examples of Present Disclosure

The present disclosure can also take the following configurations.

(1)

A power amplifier circuit including one or a plurality of amplification stages,
the power amplifier circuit comprising a first amplification stage,
wherein the first amplification stage includes
a first amplifier and a second amplifier that are configured to amplify a differential signal,
a first capacitor electrically connected between an output terminal of the first amplifier and an input terminal of the second amplifier,
a second capacitor electrically connected between an input terminal of the first amplifier and an output terminal of the second amplifier,
a first resonant circuit and a first resistor that are electrically connected in series with each other and are electrically connected between the output terminal and the input terminal of the first amplifier, and
a second resonant circuit and a second resistor that are electrically connected in series with each other and are electrically connected between the output terminal and the input terminal of the second amplifier.
   (2)

The power amplifier circuit according to the above (1),
wherein each resonant circuit includes
an LC parallel resonant circuit including an inductor and a capacitor electrically connected in parallel with each other.
   (3)

The power amplifier circuit according to the above (2),
wherein the resonant circuit further includes
another capacitor electrically connected in series with the LC parallel resonant circuit.
   (4)

The power amplifier circuit according to the above (2) or (3),
wherein a resonant frequency of the resonant circuit is
not less than a maximum frequency of a frequency band of an input radio-frequency signal.
   (5)

The power amplifier circuit according to the above (3) or (4), further comprising
a bias circuit,
wherein, in at least one of the first amplifier and the second amplifier, a power supply voltage is adjusted by using an envelope tracking method.
   (6)

The power amplifier circuit according to the above (1),
wherein each resonant circuit includes
an LC series resonant circuit including an inductor and a capacitor electrically connected in series with each other.
   (7)

The power amplifier circuit according to the above (6),
wherein a resonant frequency of the resonant circuit is
not more than a minimum frequency of a frequency band of an input radio-frequency signal.
   (8)

The power amplifier circuit according to the above (6) or (7), further comprising
a bias circuit,
wherein, in at least one of the first amplifier and the second amplifier, a power supply voltage is adjusted by using an envelope tracking method.
   (9)

The power amplifier circuit according to any one of the above (1) to (8),
wherein a fractional band width ranges from 40% to 60%.
   (10)

The power amplifier circuit according to any one of the above (1) to (9), further comprising
a second amplification stage subsequent to the first amplification stage,
wherein the second amplification stage includes a third amplifier and a fourth amplifier that are configured to amplify a differential signal,
a third capacitor electrically connected between an output terminal of the third amplifier and an input terminal of the fourth amplifier, and
a fourth capacitor electrically connected between an input terminal of the third amplifier and an output terminal of the fourth amplifier.
   (11)

The power amplifier circuit according to the above (10),
wherein each resonant circuit includes
an LC parallel resonant circuit including an inductor and a capacitor electrically connected in parallel with each other.
   (12) The power amplifier circuit according to the above

(11),
wherein the resonant circuit further includes
another capacitor electrically connected in series with the LC parallel resonant circuit.
   (13)

The power amplifier circuit according to the above (10),
wherein each resonant circuit includes
an LC series resonant circuit including an inductor and a capacitor electrically connected in series with each other.
   (14)

The power amplifier circuit according to the above (12) or (13), further comprising
a bias circuit,
wherein, in at least one of the first amplifier and the second amplifier, a power supply voltage is adjusted by using an envelope tracking method.
   (15)

The power amplifier circuit according to any one of the above (1) to (9), further comprising
a second amplification stage subsequent to the first amplification stage,
wherein the second amplification stage includes
a third amplifier and a fourth amplifier that are configured to amplify a differential signal,
a third capacitor electrically connected between an output terminal of the third amplifier and an input terminal of the fourth amplifier,
a fourth capacitor electrically connected between an input terminal of the third amplifier and an output terminal of the fourth amplifier,
a third resonant circuit and a third resistor that are electrically connected in series with each other and are electrically connected between the output terminal and the input terminal of the third amplifier, and
a fourth resonant circuit and a fourth resistor that are electrically connected in series with each other and are electrically connected between the output terminal and the input terminal of the fourth amplifier.
   (16)

The power amplifier circuit according to the above (15), further comprising
a third amplification stage subsequent to the second amplification stage,
wherein the third amplification stage includes
a fifth amplifier and a sixth amplifier that are configured to amplify a differential signal,
a fifth capacitor electrically connected between an output terminal of the fifth amplifier and an input terminal of the sixth amplifier, and
a sixth capacitor electrically connected between an input terminal of the fifth amplifier and an output terminal of the sixth amplifier.
   (17)

The power amplifier circuit according to any one of the above (10) to (16), further comprising
a third amplification stage subsequent to the second amplification stage,
wherein the second amplification stage includes
a third amplifier and a fourth amplifier that are configured to amplify a differential signal,
a third capacitor electrically connected between an output terminal of the third amplifier and an input terminal of the fourth amplifier,
a fourth capacitor electrically connected between an input terminal of the third amplifier and an output terminal of the fourth amplifier,
a third resonant circuit and a third resistor that are electrically connected in series with each other and are electrically connected between the output terminal and the input terminal of the third amplifier, and
a fourth resonant circuit and a fourth resistor that are electrically connected in series with each other and are electrically connected between the output terminal and the input terminal of the fourth amplifier.
   (18)

A power amplifier circuit including a plurality of amplification stages,
the power amplifier circuit comprising:
a first amplification stage; and
a second amplification stage subsequent to the first amplification stage,
wherein the first amplification stage includes
a first amplifier, and
a first resonant circuit and a first resistor that are electrically connected in series with each other and are electrically connected between an output terminal and an input terminal of the first amplifier, and
wherein the second amplification stage includes
a third amplifier and a fourth amplifier that are configured to amplify a differential signal,
a third capacitor electrically connected between an output terminal of the third amplifier and an input terminal of the fourth amplifier, and
a fourth capacitor electrically connected between an input terminal of the third amplifier and an output terminal of the fourth amplifier.
   (19)

The power amplifier circuit according to the above (18),
wherein the first amplification stage further includes
a second amplifier, and
a second resonant circuit and a second resistor that are electrically connected in series with each other and are electrically connected between an output terminal and an input terminal of the second amplifier, and
wherein the first amplifier and the second amplifier are configured to amplify a differential signal.
   (20)

The power amplifier circuit according to the above (15), (16), (17), (18), or (19),
wherein each resonant circuit includes
an LC parallel resonant circuit including an inductor and a capacitor electrically connected in parallel with each other.
   (21)

The power amplifier circuit according to the above (15), (16), (17), (18), or (19),
wherein each resonant circuit includes
an LC series resonant circuit including an inductor and a capacitor electrically connected in series with each other.
   (22)

The power amplifier circuit according to the above (20) or (21),
wherein the resonant circuit further includes
another capacitor electrically connected in series with the LC parallel resonant circuit.
   (23)

The power amplifier circuit according to the above (20), (21), or (22), further comprising
a bias circuit,
wherein, in at least one of the first amplifier and the second amplifier, a power supply voltage is adjusted by using an envelope tracking method.

The above-described embodiments are intended to facilitate understanding of the present disclosure but are not intended for a limited interpretation of the present disclosure. The present disclosure can be changed or improved without necessarily departing from the gist thereof and also encompasses equivalents thereof.

### REFERENCE SIGNS LIST

1, 1A, 1B, 1C, 1D, 1E, 1F, 1G, 1H, 1I, 1J power amplifier circuit
11, 12, 13, 14, 15, 16 amplifier
21, 22, 23, 24, 25, 26, 52, 62 capacitor
31, 31A, 31B, 32, 32A, 32B, 33B, 34B resonant circuit
41, 42, 43, 44 resistor
51, 61 inductor
121, 122, 131, 132 matching network

1. A power amplifier circuit comprising a first amplification stage, wherein the first amplification stage comprises:
a first amplifier and a second amplifier that are configured to amplify a differential signal;
a first capacitor electrically connected between an output terminal of the first amplifier and an input terminal of the second amplifier;
a second capacitor electrically connected between an input terminal of the first amplifier and an output terminal of the second amplifier;
a first resonant circuit and a first resistor that are electrically connected in series with each other and are electrically connected between the output terminal of the first amplifier and the input terminal of the first amplifier; and
a second resonant circuit and a second resistor that are electrically connected in series with each other and are electrically connected between the output terminal of the second amplifier and the input terminal of the second amplifier.

2. The power amplifier circuit according to claim 1, wherein each resonant circuit comprises an LC parallel resonant circuit comprising an inductor and a capacitor electrically connected in parallel with each other.

3. The power amplifier circuit according to claim 2, wherein the resonant circuit further comprises another capacitor electrically connected in series with the LC parallel resonant circuit.

4. The power amplifier circuit according to claim 2, wherein a resonant frequency of the resonant circuit is not less than a maximum frequency of a frequency band of an input radio-frequency signal.

5. The power amplifier circuit according to claim 3, further comprising:
a bias circuit,
wherein a power supply voltage of the first amplifier or the second amplifier is adjusted based on an envelope tracking method.

6. The power amplifier circuit according to claim 1, wherein each resonant circuit comprises an LC series resonant circuit comprising an inductor and a capacitor electrically connected in series with each other.

7. The power amplifier circuit according to claim 6, wherein a resonant frequency of the resonant circuit is not more than a minimum frequency of a frequency band of an input radio-frequency signal.

8. The power amplifier circuit according to claim 6, further comprising:
a bias circuit,
wherein a power supply voltage of the first amplifier or the second amplifier is adjusted based on an envelope tracking method.

9. The power amplifier circuit according to claim 1, wherein a fractional band width ranges from 40% to 60%.

10. The power amplifier circuit according to claim 1, further comprising:
a second amplification stage subsequent to the first amplification stage,
wherein the second amplification stage comprises:
a third amplifier and a fourth amplifier that are configured to amplify a differential signal;
a third capacitor electrically connected between an output terminal of the third amplifier and an input terminal of the fourth amplifier; and
a fourth capacitor electrically connected between an input terminal of the third amplifier and an output terminal of the fourth amplifier.

11. The power amplifier circuit according to claim 10, wherein each resonant circuit comprises an LC parallel resonant circuit comprising an inductor and a capacitor electrically connected in parallel with each other.

12. The power amplifier circuit according to claim 11, wherein the resonant circuit further comprises another capacitor electrically connected in series with the LC parallel resonant circuit.

13. The power amplifier circuit according to claim 10, wherein each resonant circuit comprises an LC series resonant circuit comprising an inductor and a capacitor electrically connected in series with each other.

14. The power amplifier circuit according to claim 12, further comprising:
a bias circuit,
wherein a power supply voltage of the first amplifier or the second amplifier is adjusted based on an envelope tracking method.

15. The power amplifier circuit according to claim 1, further comprising:
a second amplification stage subsequent to the first amplification stage,
wherein the second amplification stage comprises:
a third amplifier and a fourth amplifier that are configured to amplify a differential signal;
a third capacitor electrically connected between an output terminal of the third amplifier and an input terminal of the fourth amplifier;
a fourth capacitor electrically connected between an input terminal of the third amplifier and an output terminal of the fourth amplifier;
a third resonant circuit and a third resistor that are electrically connected in series with each other and are electrically connected between the output terminal of the third amplifier and the input terminal of the third amplifier; and
a fourth resonant circuit and a fourth resistor that are electrically connected in series with each other and are electrically connected between the output terminal of the fourth amplifier and the input terminal of the fourth amplifier.

16. The power amplifier circuit according to claim 15, further comprising:
a third amplification stage subsequent to the second amplification stage,
wherein the third amplification stage comprises:
a fifth amplifier and a sixth amplifier that are configured to amplify a differential signal;
a fifth capacitor electrically connected between an output terminal of the fifth amplifier and an input terminal of the sixth amplifier; and
a sixth capacitor electrically connected between an input terminal of the fifth amplifier and an output terminal of the sixth amplifier.

17. The power amplifier circuit according to claim 10, further comprising:
a third amplification stage subsequent to the second amplification stage,
wherein the second amplification stage comprises:
a third amplifier and a fourth amplifier that are configured to amplify a differential signal;
a third capacitor electrically connected between an output terminal of the third amplifier and an input terminal of the fourth amplifier;
a fourth capacitor electrically connected between an input terminal of the third amplifier and an output terminal of the fourth amplifier;
a third resonant circuit and a third resistor that are electrically connected in series with each other and are electrically connected between the output terminal of the third amplifier and the input terminal of the third amplifier; and
a fourth resonant circuit and a fourth resistor that are electrically connected in series with each other and are electrically connected between the output terminal of the fourth amplifier and the input terminal of the fourth amplifier.

18. A power amplifier circuit comprising a plurality of amplification stages, the power amplifier circuit comprising:
a first amplification stage; and
a second amplification stage subsequent to the first amplification stage,
wherein the first amplification stage comprises:
a first amplifier; and
a first resonant circuit and a first resistor that are electrically connected in series with each other and are electrically connected between an output terminal of the first amplifier and an input terminal of the first amplifier, and
wherein the second amplification stage comprises:
a third amplifier and a fourth amplifier that are configured to amplify a differential signal;
a third capacitor electrically connected between an output terminal of the third amplifier and an input terminal of the fourth amplifier; and
a fourth capacitor electrically connected between an input terminal of the third amplifier and an output terminal of the fourth amplifier.

19. The power amplifier circuit according to claim 18,
wherein the first amplification stage further comprises:
a second amplifier; and
a second resonant circuit and a second resistor that are electrically connected in series with each other and are electrically connected between an output terminal of the second amplifier and an input terminal of the second amplifier, and
wherein the first amplifier and the second amplifier are configured to amplify a differential signal.

20. The power amplifier circuit according to claim 15,
wherein each resonant circuit comprises an LC parallel resonant circuit comprising an inductor and a capacitor electrically connected in parallel with each other, or
wherein each resonant circuit comprises an LC series resonant circuit comprising an inductor and a capacitor electrically connected in series with each other.
